(19) United States
(12) Patent Application Publication
(10) Pub. No.: US 2005/0255642 A1
(43) Pub. Date: Nov. 17, 2005

(54) Method of fabricating inlaid structure

(76) Inventors: Chi-Wen Liu, Hsinchu (TW); Jung-Chih Tsao, Taipei (TW)

Correspondence Address: BIRCH STEWART KOLASCH & BIRCH, PO BOX 747, FALLS CHURCH, VA, 22040-0747, US

(21) Appl. No.: 10/842,454

(22) Filed: May 11, 2004

(51) Int. Cl. H01L 21/338; H01L 21/4763; H01L 21/302; H01L 21/461

(52) U.S. Cl. 438/183; 438/638; 438/692

(57) ABSTRACT

A method of fabricating an inlaid structure. A sacrificial layer having a trench opening over a substrate is provided. A metal layer is deposited over the sacrificial layer filling the trench openings. A first CMP is performed to remove excess metal layer above the sacrificial layer to form an interconnect structure. The sacrificial layer is removed to expose the interconnect structure. A first dielectric layer is deposited over the substrate covering the interconnect structure. A second CMP is performed on the first dielectric layer to planarize the first dielectric layer.

### BACKGROUND OF THE INVENTION

1. Field of the Invention

The present invention relates to a method of fabricating an inlaid structure, and more particularly, to a method of fabricating an inlaid structure utilizing a sacrificial layer.

2. Description of the Related Art

In current IC fabrication, interconnections between metal levels, such as copper, separated by inter-layered dielectric, are typically formed with a damascene method of via formation between metal levels. The first metal pattern is first completely covered with low-k dielectric. A trench is patterned into the low-k dielectric layer. A via is patterned from the trench, through the low-k dielectric layer, to the first metal pattern. A metal film, such as copper, then fills the via and the trench. A layer consisting of dielectric with a metal via through it now overlies the first metal pattern. The excess metal can be removed using chemical mechanical polishing (CMP), as is well known in the art. The result is an inlaid or damascene metal structure.

However, chemical mechanical polishing (CMP) of copper layers produces dishing and erosion issues for the copper damascene. Dishing causes reduced yields, unreliability and unacceptable performance. Additionally, low k dielectric material with low mechanical strength can be damaged during chemical mechanical polishing, by slurry diffusing into the low k dielectric material. Solutions to these problems are necessary to prevent contamination and infiltration of slurry resulting in various defects, e.g., slurry residue, broken portions of the copper damascene, and particles, which, in turn, affect the yield of the resulting semiconductor device.

### SUMMARY OF THE INVENTION

An object of the present invention is to provide a sacrificial layer for fabricating an inlaid structure to overcome the dishing and erosion problems caused by chemical mechanical polishing (CMP).

Another object of the present invention is to provide a method for prevention of residual slurry, thereby eliminating problems in subsequent processing operations which lead to contamination, electrical device opens, electrical device shorts and other yield/reliability concerns.

To obtain the above objects, the present invention provides a sacrificial layer on substrate surface during CMP of metal inlaid structures. The sacrificial layer is subsequently removed and a new, contamination-free dielectric layer is provided surrounding the metal inlaid structure. The present invention provides a novel process for prevention of problems in subsequent processing operations which lead to contamination, electrical device opens, electrical device shorts and other yield/reliability concerns.

In one aspect of the present invention, a method of fabricating an integrated circuit device is provided. The method comprises providing a sacrificial layer having an opening on a substrate, forming an inlaid element in the opening and planarizing the same by a first chemical mechanical polishing (CMP), removing the sacrificial layer to expose the inlaid element, forming a dielectric layer on the substrate covering the inlaid element, and planarizing the dielectric layer by a second chemical mechanical polishing (CMP).

In another aspect of the present invention, a method of fabricating an integrated circuit device is provided. The method comprises providing a semiconductor substrate having a sacrificial layer thereon, and a dummy gate structure created within the sacrificial layer, removing the dummy gate structure to form a groove, forming a gate dielectric and metal gate over the sacrificial layer filling the groove, performing a first CMP to remove the excess metal above the sacrificial layer to create a metal gate structure, removing the sacrificial layer to expose the metal gate structure, forming a dielectric layer over the substrate covering the metal gate structure, and performing a second CMP on the dielectric layer to planarize the dielectric layer.

In further another aspect of the present invention, a method of fabricating an integrated circuit device is provided. The method comprises providing a semiconductor substrate having a first dielectric layer thereon and a first metal electrode disposed within the first dielectric layer, forming a sacrificial layer having an opening to the first metal electrode over the first dielectric, depositing a high-k dielectric layer over the sacrificial layer covering and lining the opening, depositing a second metal electrode over the sacrificial layer filling the opening, performing a first CMP to remove the excess second metal electrode above the sacrificial layer creating a metal-insulator-metal (MIM) structure, removing the sacrificial layer to expose the metal-insulator-metal (MIM) structure, forming a second dielectric layer on the substrate covering the metal-insulator-metal (MIM) structure, and performing a second CMP on the second dielectric layer to planarize the second dielectric layer.

### BRIEF DESCRIPTION OF THE DRAWINGS

The present invention can be more fully understood by reading the subsequent detailed description in conjunction with the examples and references made to the accompanying drawings, wherein:

FIGS. 1A-1H are schematic diagrams illustrating a method for fabrication of copper damascene with low k dielectric using a sacrificial layer according to the first embodiment of the present invention;

FIGS. 2A-2G are schematic diagrams illustrating a method for fabrication of metal gate MOS field effect transistor with low k dielectric using a sacrificial layer according to the second embodiment of the present invention; and

FIGS. 3A-3G are schematic diagrams illustrating a method for fabrication of metal-insulator-metal (MIM) capacitor with low k dielectric using a sacrificial layer according to the third embodiment of the present invention.

### DETAILED DESCRIPTION OF THE INVENTION

The present invention, which provides a method of fabricating an inlaid structure using a sacrificial layer, is described in greater detail by referring to the drawings that accompany the present invention. It is noted that in the accompanying drawings, like and/or corresponding elements are referred to by like reference numerals.

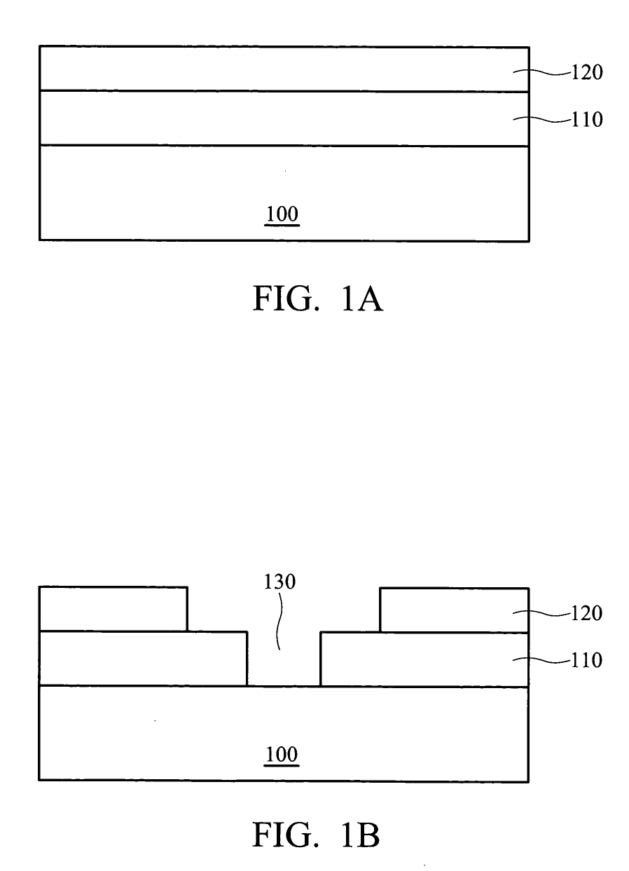

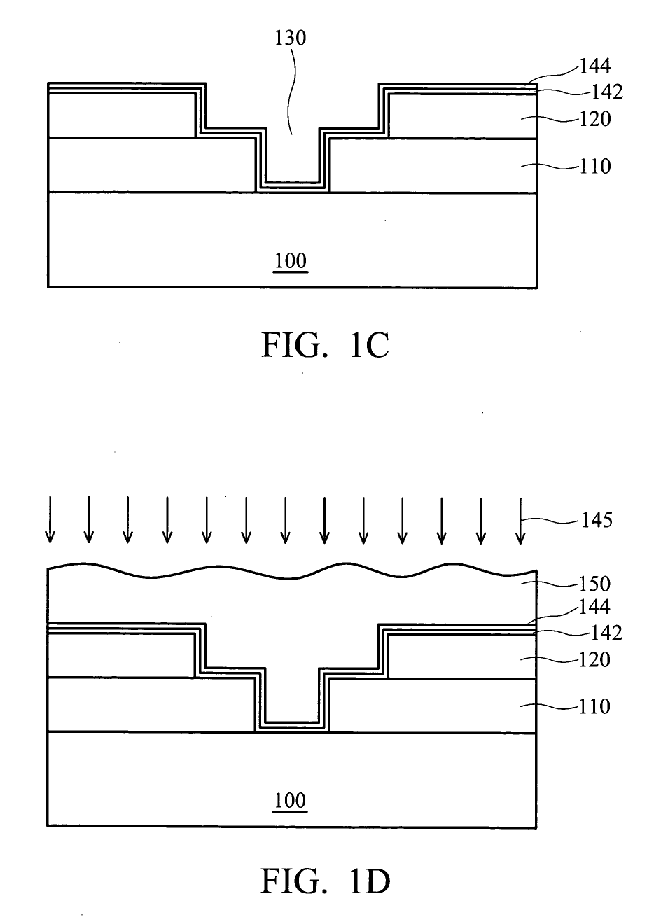

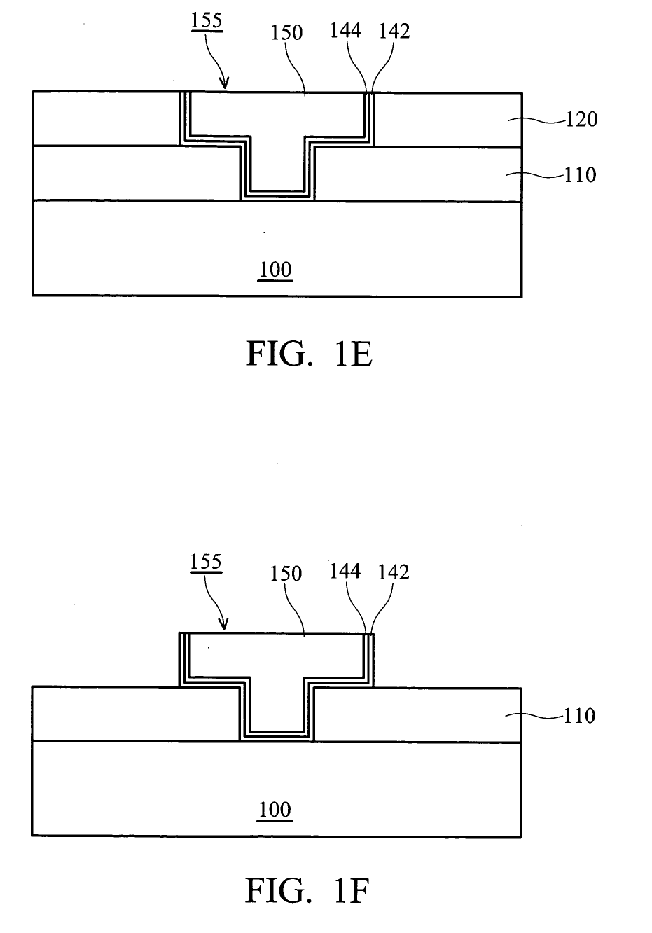

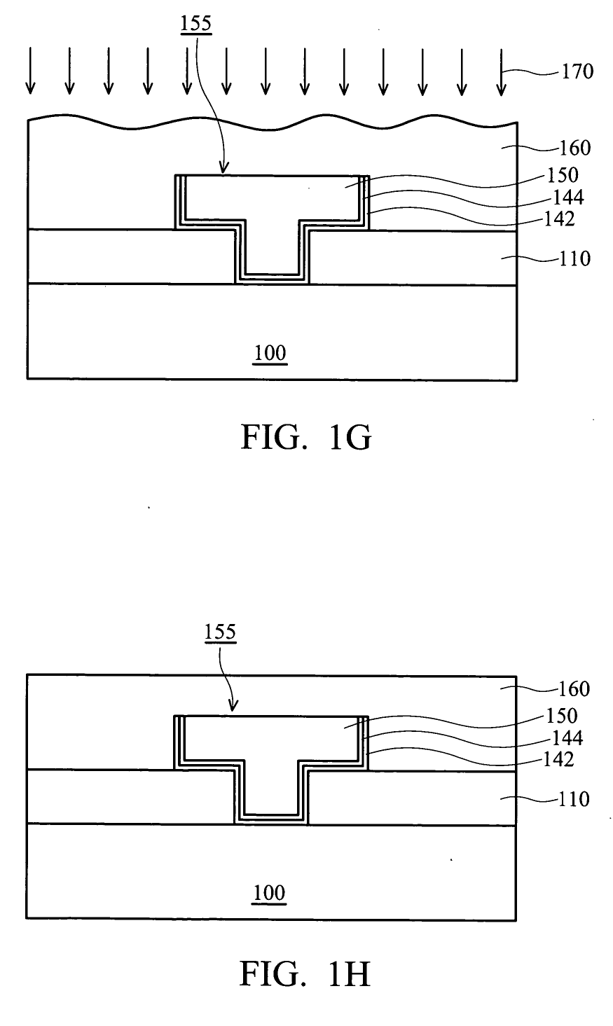

FIGS. 1A-1H are schematic diagrams illustrating a method for fabrication of copper damascene with low k dielectric using a sacrificial layer according to the first embodiment of the present invention.

The low k dielectrics used in the present invention are preferred, dielectrics without limiting to the disclosure thereto, preferably having a dielectric constant of below 2.8 and even more preferably having a dielectric constant in the range of 2.2 to 2.5, such as, low K dielectric materials comprising fluorine-doped SiO₂ (FSG), polyimide, polysilsesquiozane (Si polymer), benzocyclobutene (BCB), parylane N, fluorinated polyimide, parylane P, or amorphous Teflon. Extremely low k dielectric is preferably formed of an oxide and methylsilsesquioxane (MSQ) hybrid, an MSQ derivative, a porogen/MSQ hybrid, an oxide/hydrogen silsesquioxane (HSQ) hybrid, an HSQ derivative, a porogen/HSQ hybrid, and the like. Other materials, such as nanoporous silica, xerogel, poly tetra fluoro ethylene (PTFE), and low k dielectrics such as SILK available from Dow Chemical, FLARE, available from Allied Signal, and Black Diamond, available from Applied Materials, may also be employed.

Referring to FIG. 1A, a substrate 100 is provided with a low k dielectric layer 110 formed thereon. The low k dielectric layer 110 is preferably plasma treated or thermal annealed to stabilize and improve quality. A sacrificial layer 120 is formed on the low k dielectric 110. The sacrificial layer 120 is silicon oxide, silicon nitride, silicon oxynitride (SiON) or carbon doped silicon nitride. Alternatively, the sacrificial layer 120 can be organic material such as polymer with CMP resistance.

Referring to FIG. 1B, a damascene opening 130 is formed in the low k dielectric layer 110 and sacrificial layer 120, followed by a barrier layer 142 conforming to a profile of the damascene opening 130 over the substrate 100. The barrier layer 142 comprising materials which can prevent copper diffusion through the low k dielectric layer 110, preferably comprising tantalum (Ta), tantalum nitride (TaN), tungsten nitride (WN), or Ta/TaN. The method of forming the barrier layer 142 includes physical vapor deposition (PVD) . A copper seed layer 144 is then formed on the barrier layer 142 to improve quality of a copper layer formed subsequently, as shown in FIG. 1C.

Although the damascene opening 130 shown in FIG. 1C is a dual damascene opening comprising a via hole (a narrow part of the damascene opening 130) and a trench (a wide part of the damascene opening 130), the damascene opening can be merely a via hole or a trench.

Referring to FIGS. 1D through 1E, a copper layer 150 is formed on the copper seed layer 144, wherein the copper layer 150 is thick enough that the damascene opening 130 is filled. The method for forming the copper layer 150 can comprise electrochemical deposition (ECD), physical vapor deposition (PVD), chemical vapor deposition (CVD), and others.

A first chemical mechanical polishing (CMP) 145 is performed, providing a polishing rate for the copper layer 150 substantially faster than that for the sacrificial layer 120. Acid slurry, of SiO₂, Al₂O₃ or other ceramic powders as abrasives, H₂O₂ and organic acid as oxidizers, and a surfactant is selected to remove portions of the copper layer 150, the copper seeding layer 144, and the barrier layer 142 outside the damascene opening 130, to form a copper damascene 155. The copper damascene 155 is in this case a dual copper damascene comprising a copper plug and a copper line. The pH value of the acid slurry can be adjusted to achieve desired polishing selectivity. For example, the pH value of the slurry can be kept at between about 3 and 7. In addition, polishing step 145 is performed at a pressure of about 300-400 g/cm².

Accordingly, the use of sacrificial layer 120 can prevent acid slurry diffusion into the low k dielectric 110 and react with the low k dielectric 110.

Referring to FIG. 1F, the sacrificial layer 120 is removed by a chemical such as hydrofluoric acid or phosphorous acid.

Referring to FIGS. 1G through 1H, a second low k dielectric layer 160 is formed on the first low k dielectric layer 110 covering the copper interconnect 155. The second low k dielectric layer 160 is plasma treated or thermal annealed to stabilize and improve quality of the low k dielectric 160.

A second chemical mechanical polishing (CMP) step 170 is performed. For instance, the polishing step 170 can be performed using alkaline slurry, of SiO₂, Al₂O₃ or other ceramic powders as abrasives, H₂O₂ and organic acid as oxidizers, and a surfactant. The pH value of the slurry can be adjusted to achieve desired polishing selectivity. For example, the pH value of the slurry can be kept above about 10. In addition, the polishing step 170 is performed at a pressure of about 300-400 g/cm².

Further, those skilled in the art would appreciate that other inlaid structures, such as metal gate MOS structure and metal-insulator-metal (MIM) capacitor, are also applicable to the present invention.

Second Embodiment

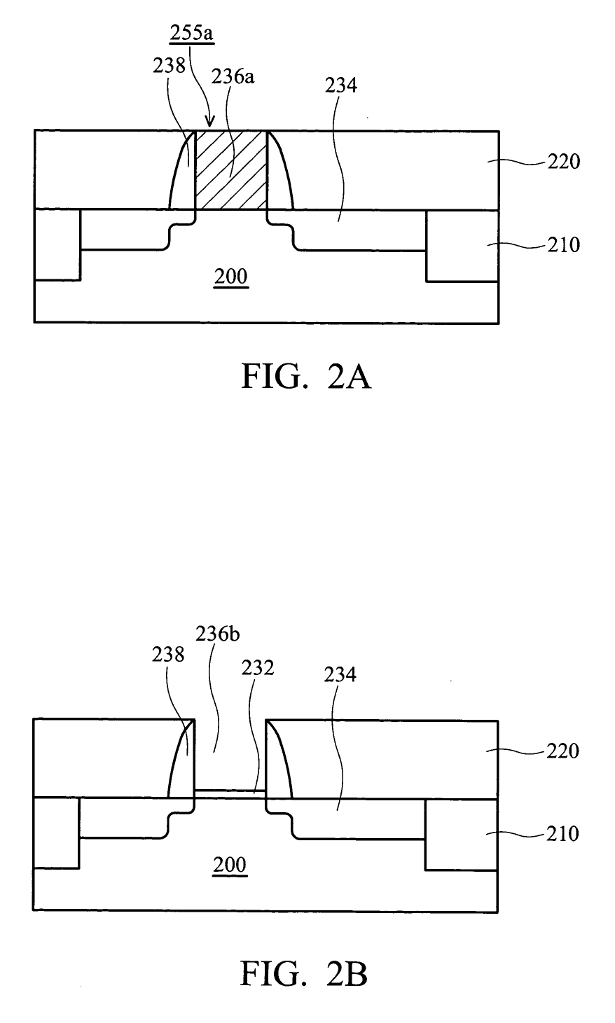

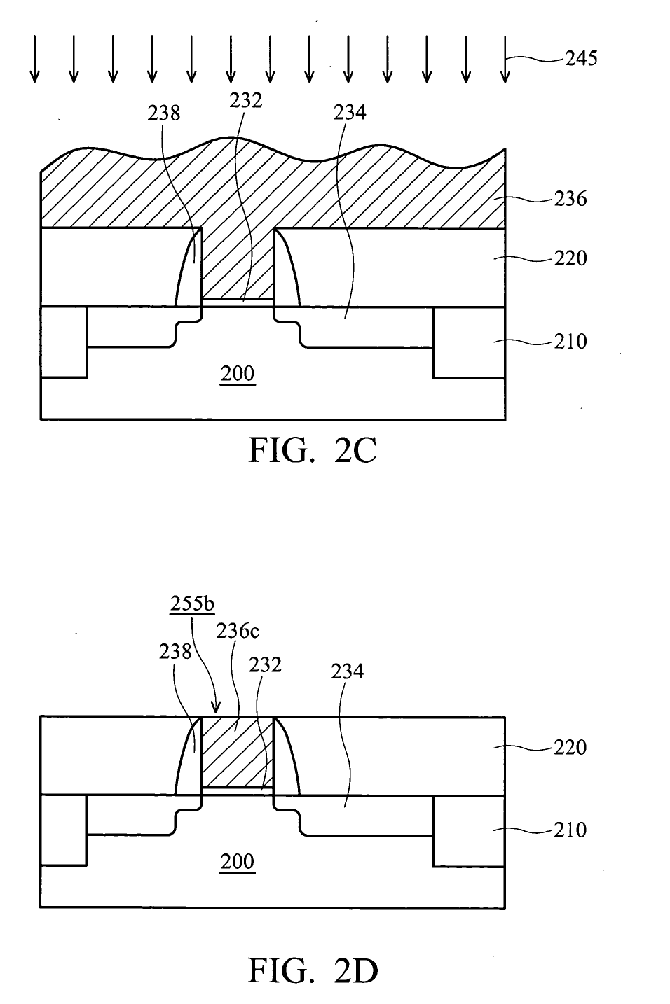

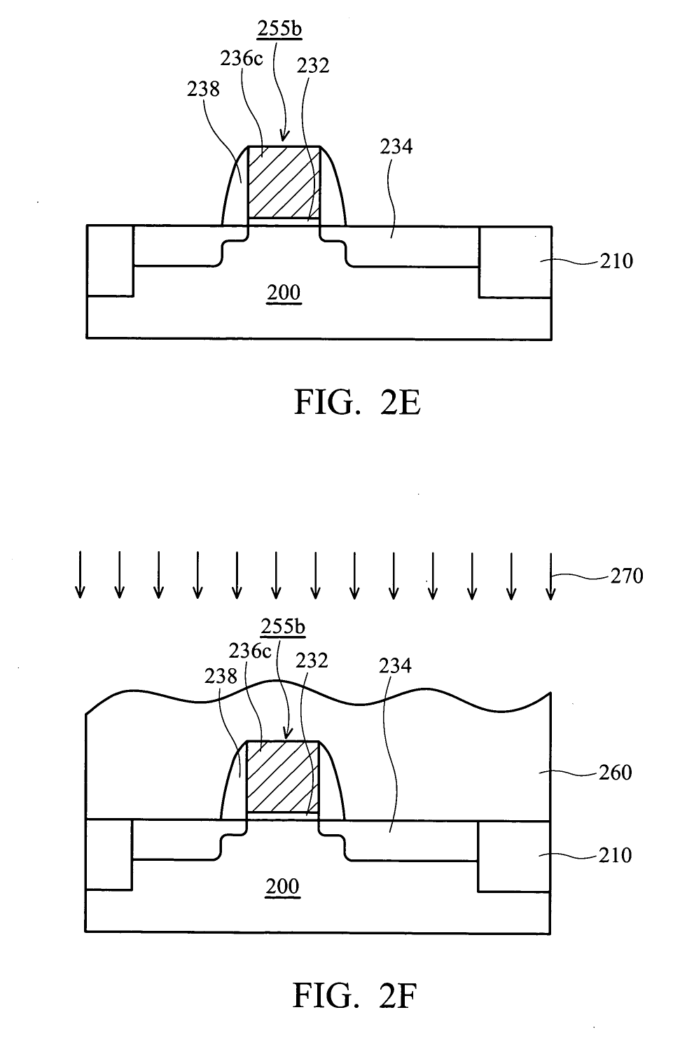

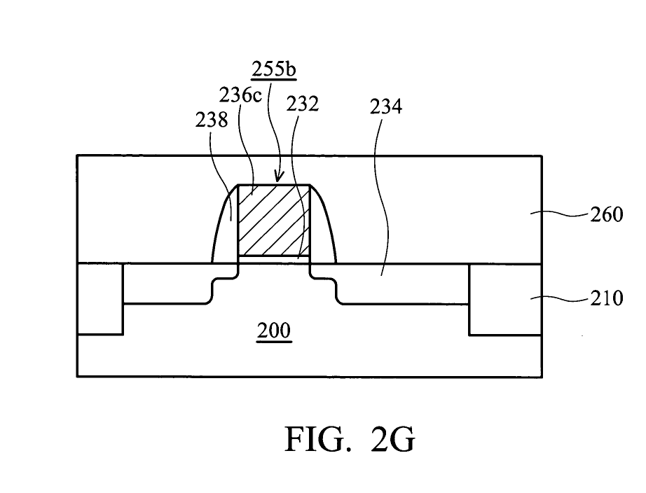

FIGS. 2A-2G are schematic diagrams illustrating a method for fabrication of metal gate MOS field effect transistor with low k dielectric using a sacrificial layer according to the second embodiment of the present invention.

FIG. 2A is a cross section of a dummy gate MOS structure 255 overlying a semiconductor substrate 120, preferably a monocrystalline silicon substrate 120. Isolation regions 210 are created in the surface of the substrate 200 to define and electrically isolate active surface regions in the surface thereof.

The dummy gate MOS structure 255a comprises a dummy gate on the surface of the substrate 200. Layers 232 and 236a are part of the gate electrode. Lightly Doped (LDD) source implants and drain implants are created self-aligned with the gate structure, extending laterally along the surface of substrate 200. Spacers 238 are formed on the sidewall of the stacked dummy gate 236a and gate oxide 232. Source regions 234 are then formed in the surface of substrate 200.

The dummy gate MOS structure 255 is insulated by sacrificial layer 220. The sacrificial layer 220 is silicon oxide, silicon nitride, silicon oxynitride (SiON) or carbon doped silicon nitride. Alternatively, the sacrificial layer 220 can be organic material such as polymer with CMP resistance.

In FIG. 2B, the dummy gate 236a is removed, creating an opening 236b. A gate dielectric 232 is formed on the bottom of the opening 236b.

In FIGS. 2C through 2D, metal layer 236 is formed on the sacrificial layer 220, wherein the copper layer 236 is thick enough that the gate opening 236b is filled. The method for forming metal layer 236 can comprise ECD, PVD, or CVD.

A first chemical mechanical polishing (CMP) 245 is performed, providing a polishing rate for metal layer 236 substantially faster than that for the sacrificial layer 220. Acid slurry, of SiO₂, Al₂O₃ or other ceramic powders as abrasives, H₂O₂ and organic acid as oxidizers, and a surfactant removes portions of the copper layer 236 outside the gate opening 236b, to form a metal gate 236c. The pH value of the acid slurry can be adjusted to achieve desired polishing selectivity. For example, the pH value of the slurry can be kept between about 3 and 7. In addition, the polishing step 245 is performed at a pressure of about 300-400 g/cm².

Referring to FIG. 2E, the sacrificial layer 220 is removed by a chemicals such as hydrofluoric acid or phosphorous acid.

Referring to FIGS. 2F through 2G, a second low k dielectric layer 260 is formed overlying the substrate 200 covering the metal gate MOS structure 255. The second low k dielectric layer 260 undergoes plasma treatment or thermal annealing to stabilize and improve quality of the low k dielectric.

A second chemical mechanical polishing (CMP) step 270 is performed to planarize the second low k dielectric layer 260. For instance, the polishing step 270 can be performed using alkaline slurry, of SiO₂, Al₂O₃ or other abrasives. For example, the pH value of the slurry can be kept above about 10. In addition, the polishing step 270 is performed at a pressure of about 300-400 g/cm².

Third Embodiment

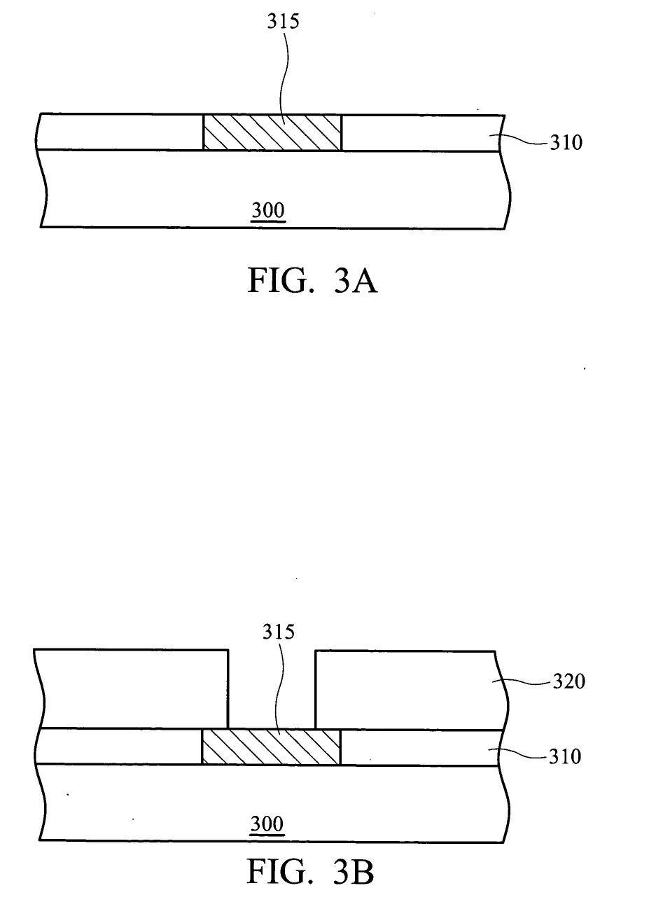

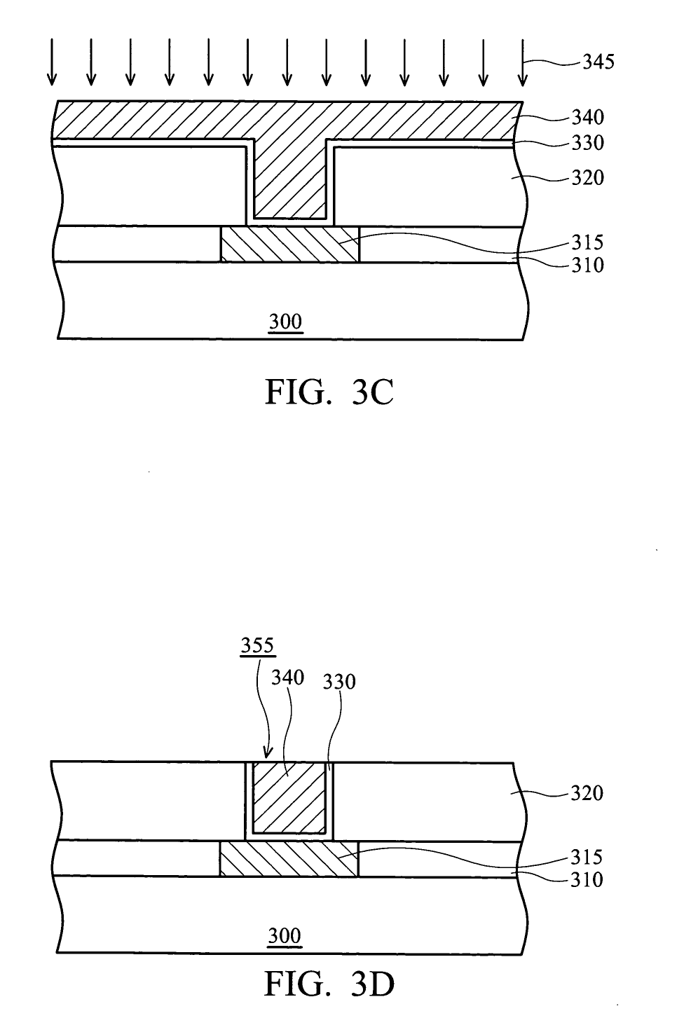

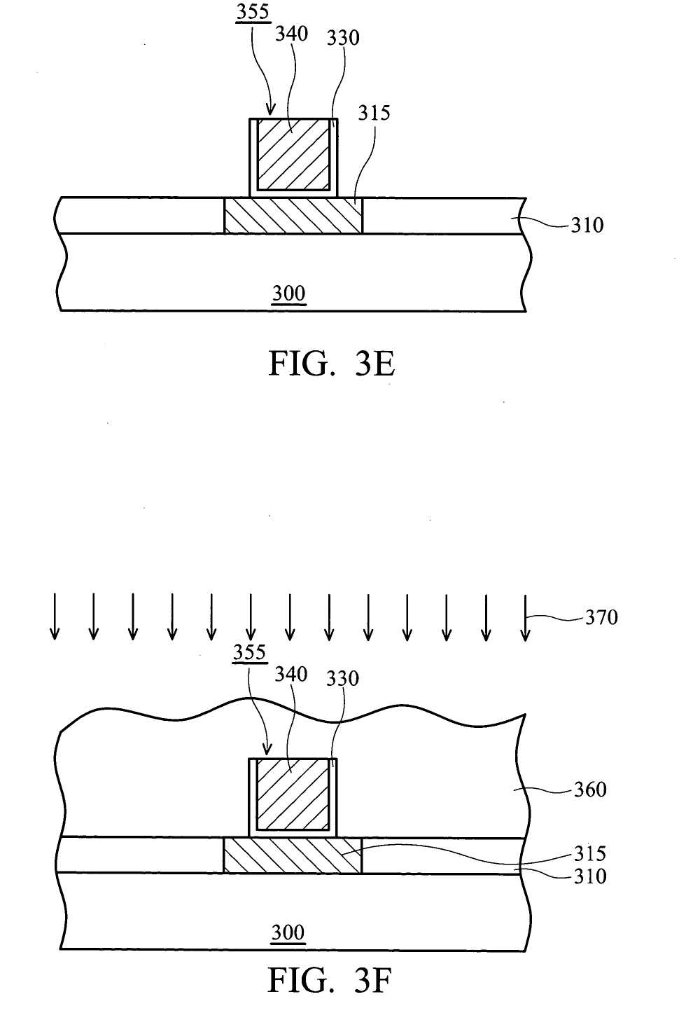

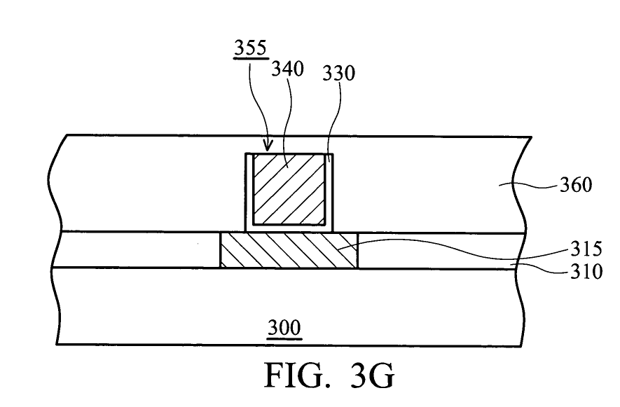

FIGS. 3A-3G are schematic diagrams illustrating a method for fabrication of metal-insulator-metal (MIM) capacitor using a sacrificial layer according to the third embodiment of the present invention.

FIG. 3A is a cross section of a semiconductor substrate 300, typically a monocrystalline silicon substrate 300, on the surface of which has been uniformly deposited a first low k dielectric layer 310. A first opening is created in the first low k dielectric layer 310 and filled with a planarized first layer of metal 315, forming a first metal plug in the first low k dielectric layer 310 to serve as a first electrode of the capacitor. Metal 315 is Cu or AlCu alloy and deposited using conventional methods of ECD, CVD or sputtering.

In FIG. 3B, a sacrificial layer 320 is deposited over the first low k dielectric layer 310, including the first electrode 315 of the capacitor. The sacrificial layer 320 is patterned, creating an opening 325 therein aligned with the first electrode 315 of the capacitor.

Referring to FIG. 3C, a capacitor dielectric layer 330 is conformally formed over the sacrificial layer 320 covering and lining the opening. The capacitor dielectric 330 may be an oxide, oxynitride or any combination thereof including multilayers. Alternatively, the capacitor dielectric 330 may be high k dielectric material such as Ta₂O₅, TiO₂, or barium strontium titanium oxide (BST). Deposition of layer 330 can comprise rf sputtering. It is well known in the art that the capacitor dielectric layer 330 must be as thin as possible in accordance with considerations of reliability since a thin layer of dielectric is required for a high capacitive value of the capacitor.

Metal layer 340 is formed on the capacitor dielectric layer 330, wherein metal layer 340 is thick enough that the opening 325 is filled. The method for forming metal layer 340 comprises ECD, PVD, or CVD.

A first chemical mechanical polishing (CMP) 345 is performed, providing a polishing rate for metal layer 340 substantially faster than that for the sacrificial layer 320. Acid slurry, of SiO₂, Al₂O₃ or other ceramic powders as abrasives, H₂O₂ and organic acid as oxidizers, and a surfactant is selected to remove portions of metal layer 340 and capacitor dielectric 330 outside the opening 325, to create a metal-insulator-metal (MIM) capacitor 355 as shown in FIG. 3D. The pH value of the slurry can be adjusted to achieve desired polishing selectivity. For example, the pH value of the slurry can be kept between about 3 and 7. In addition, the polishing step 345 is performed at a pressure of about 300-400 g/cm².

Accordingly, the use of sacrificial layer 320 prevents acid slurry diffusion into the low k dielectric 315 and reacting therewith.

Referring to FIG. 3E, the sacrificial layer 320 is removed by etching with, for example, hydrofluoric acid or phosphorous acid. Dry etching, such as reactive ion etching, can alternatively be used.

Referring to FIGS. 3F through 3G, a second low k dielectric layer 360 is formed on the first low k dielectric layer 310 covering metal-insulator-metal (MIM) capacitor 355. The second low k dielectric layer 360 undergoes plasma treatment or thermal annealing to stabilize and improve quality of the low k dielectric.

A second chemical mechanical polishing (CMP) 370 is performed to planarize the second low k dielectric layer 360. For instance, the polishing step 370 can use alkaline. slurry, of SiO₂, Al₂O₃ or other abrasives. For example, the pH value of the slurry can be kept above about 10. In addition, the polishing step 370 is performed at a pressure of about 300-400 g/cm².

The sacrificial layer according to the present invention is formed and removed during fabrication of inlaid integrated circuit devices. The present invention provides a novel process for prevention of problems in subsequent processing operations which can lead to contamination, electrical device opens, electrical device shorts and other yield/reliability concerns.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method of fabricating an integrated circuit device comprising:
providing a sacrificial layer, comprising an opening, on a substrate;
forming an inlaid element in the opening and planarizing the same by a first chemical mechanical polishing (CMP);
removing the sacrificial layer to expose the inlaid element;
forming a dielectric layer on the substrate covering the inlaid element; and
planarizing the dielectric layer by a second chemical mechanical polishing (CMP).

2. The method as claimed in claim 1, wherein the first CMP is performed using acid slurry.

3. The method as claimed in claim 1, wherein the sacrificial layer comprises silicon oxide, silicon nitride, silicon oxynitride, carbon doped silicon nitride, or CMP resistant polymer.

4. The method as claimed in claim 1, wherein the inlaid element comprises a metal damascene interconnect, a metal gate MOS transistor, or an MIM capacitor.

5. The method as claimed in claim 1, wherein the second CMP is performed using alkaline slurry.

6. A method of fabricating an integrated circuit device, comprising:
providing a semiconductor substrate, comprising a sacrificial layer thereon, and a dummy gate structure created within the sacrificial layer;
removing the dummy gate structure to form a groove;
forming a gate dielectric and metal gate over the sacrificial layer, filling the groove;
performing a first CMP to remove excess metal above the sacrificial layer to create a metal gate structure;
removing the sacrificial layer to expose the metal gate structure;
forming a dielectric layer over the substrate covering the metal gate structure; and
performing a second CMP on the dielectric layer to planarize the dielectric layer.

7. The method as claimed in claim 6, wherein the sacrificial layer comprises silicon oxide, silicon nitride, silicon oxynitride, carbon doped silicon nitride, or CMP resistant polymer.

8. The method as claimed in claim 6, wherein the metal gate comprises tungsten, molybdenum, niobium, tantalum, tantalum nitride, titanium nitride, titanium silicide, or cobalt silicide.

9. The method as claimed in claim 6, wherein the first CMP is performed using acid slurry.

10. The method as claimed in claim 6, wherein the second CMP is performed using alkaline slurry.

11. A method of fabricating an integrated circuit device, comprising:
providing a semiconductor substrate, comprising a first dielectric layer thereon and a first metal electrode disposed within the first dielectric layer;
forming a sacrificial layer comprising an opening to the first metal electrode over the first dielectric;
depositing a high-k dielectric layer over the sacrificial layer covering and lining the opening;
depositing a second metal electrode over the sacrificial layer, filling the opening;
performing a first CMP to remove excess second metal electrode above the sacrificial layer, creating a metal-insulator-metal (MIM) structure;
removing the sacrificial layer to expose the metal-insulator-metal (MIM) structure;
forming a second dielectric layer on the substrate covering the metal-insulator-metal (MIM) structure; and
performing a second CMP to planarize the second dielectric layer.

12. The method as claimed in claim 11, wherein the sacrificial layer comprises silicon oxide, silicon nitride, silicon oxynitride, carbon doped silicon nitride, or CMP resistant polymer.

13. The method as claimed in claim 11, wherein the first metal layer and the second metal layer comprise Cu or AlCu.

14. The method as claimed in claim 11, wherein the first CMP is performed using acid slurry.

15. The method as claimed in claim 11, wherein the second CMP is performed using alkaline slurry.
